(19) United States
(12) Patent Application Publication
(10) Pub. No.: US 2016/0270249 A1
(43) Pub. Date: Sep. 15, 2016

(54) MEMORY MODULE LATCHES AND EJECTORS

(71) Applicant: HEWLETT PACKARD ENTERPRISE DEVELOPMENT LP, Houston, TX (US)

(72) Inventor: Owen Oliver Kidd, Houston, TX (US)

(73) Assignee: Hewlett-Packard Development Company, L.P., Houston, TX (US)

(21) Appl. No.: 15/030,371

(22) PCT Filed: Nov. 15, 2013
(86) PCT No.: PCT/US2013/070291

§ 371 Date: Apr. 18, 2016

(51) Int. Cl. H05K 7/14; H01R 12/72; H01R 13/629

(52) U.S. Cl. CPC H05K 7/1409; H05K 7/1405; H01R 13/62977; H01R 12/721

(57) ABSTRACT

In accordance with examples provided herein, a system includes a memory connector, latch, and ejector. The memory connector is to receive a memory module usable in a computing system. The latch is to retain the memory module seated in the memory connector. The ejector is to disengage the latch into a release position, and eject the memory module, based on depressing the ejector.

### BACKGROUND

A computing system may interface with a memory module based on a socket that has swinging latches that need extra room/clearance to operate. Further, the latches may cause memory errors by failing to completely actuate and/or close properly onto the memory module, despite appearing to be closed. The latches also may easily come unlatched and allow memory modules to come loose during shipping or other jarring motions.

### BRIEF DESCRIPTION OF THE DRAWINGS/FIGURES

FIG. 1A is a side view of a system including an ejector and memory connector according to an example.

FIG. 1B is a top view of a system including an ejector and memory connector according to an example.

FIG. 1C is a bottom view of a system including an ejector and memory connector according to an example.

FIG. 1D is a front view of a system including an ejector and memory connector according to an example.

FIG. 2 is a side section view of a system including an ejector and memory connector according to an example.

FIG. 3 is a perspective view of a system including an ejector and memory connector according to an example.

FIG. 4 is a side section view of a system including an ejector and memory connector according to an example.

FIG. 5 is a side view of a system including an ejector and memory connector according to an example.

FIG. 6 is a side section view of a system including an ejector and memory connector according to an example.

FIG. 7 is a side section view of a system including an ejector and memory connector according to an example.

FIG. 8 is a side section view of a system including an ejector and latch according to an example.

FIG. 9 is a side section view of a system including an ejector and latch according to an example.

FIG. 10 is an exploded perspective view of a system including an ejector housing and memory connector according to an example.

### DETAILED DESCRIPTION

Examples provided herein may address a high rate of latching failures for system memory modules, while enabling placement of memory module sockets (i.e., memory connectors) in closer proximity to each other. Examples may provide audible and visible verifications of proper memory module latch engagement, avoiding incomplete memory module seating and preventing components from assuming a position that appears latched despite actually being unlatched. Examples may be based on, e.g., a vertical latch disengagement mechanism having no need for lateral latch movement and associated needs for extra clearance/room (e.g., no need to accommodate a laterally swinging latch). Examples also may provide memory insertion and/or ejection based on a single comfortable movement (e.g., one-push insertion/ejection), without a need to pull or pivot components and/or the memory module.

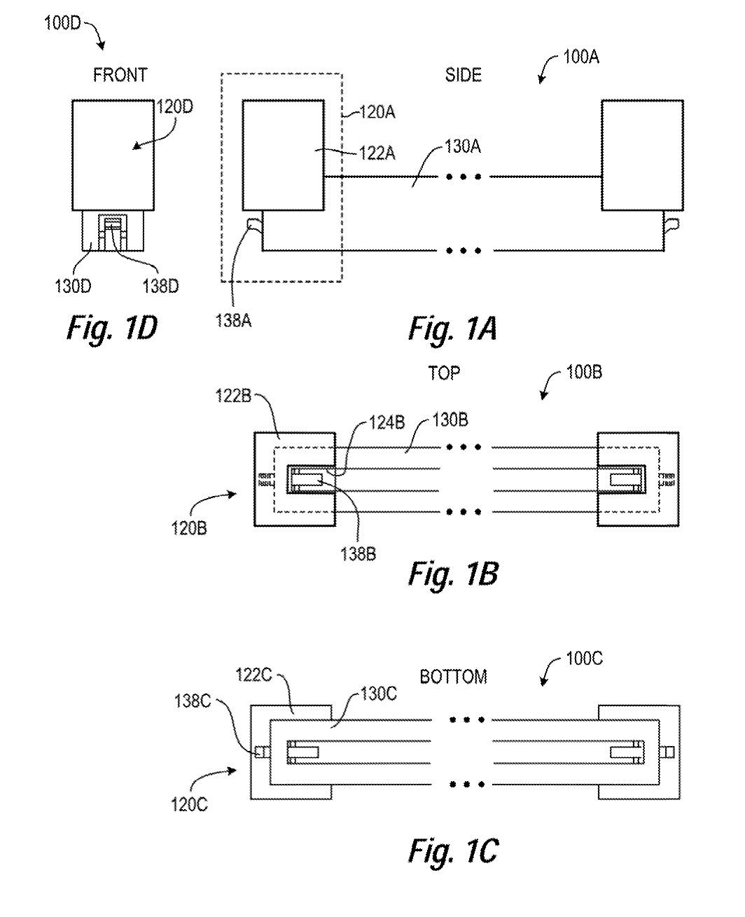

FIG. 1A is a side view of a system 100A including an ejector 120A and memory connector 130A according to an example. The system 100A also includes an ejector housing 122A and lever 138A. The memory connector 130A is to receive and retain a memory module based on a latch (not shown in FIG. 1A). The ejector 120A is to enable the memory module to be ejected, based on operation of the ejector housing 122A and/or the lever 138A.

Example systems may be compliant with various types of memory and memory standards. For example, system 100A may comply with single in-line memory modules (SIMMs), dual in-line memory modules (DIMMs), and others. System 100A may comply with standards such as the Joint Electron Devices Engineering Council (JEDEC) Solid State Technology Association's JESD79-3E document defining support for memory modules such as various dynamic random access memory (DRAM) modules including double data rate (DDRx), where x is an integer indicating memory variation (e.g., DDR2, DDR3, DDR4, and so on). However, system 100A may be compliant with other memory standards and modules, including synchronous, asynchronous, graphics, and other types of memory modules that interface with a latch.

System 100A may be based on a vertically latching-and-releasing memory module connector. For example, the ejector housing 122A of the ejector 120A may be movable in an upward and downward (as shown in FIG. 1A) direction, e.g., to interact with lever 138A. Accordingly, the system 100A provides the benefit of enabling memory connectors 130A to be placed in closer proximity to each other in a given computing system, such as on a server computer motherboard having multiple memory connectors 130A. Vertical ejector operation enables the system 100A to operate without needing lateral movements or increased spacing on sides of the system 100A. Latching actuation is confined within the footprint of the system 100A. In alternate embodiments, however, actuation of the ejector 120A may include lateral movements. For example, the ejector housing 122A may slide along a non-vertical path, incorporate some pivoting or slanting motions, or other alternatives, while enabling the one-press ejector operation.

Thus, system 100A enables a memory module to be inserted and retained easily, without encountering resistance associated with a need to actuate pivoting levers or other cumbersome latching components. System 100A also enables confirmation of proper memory module engagement, and easy operation to eject the memory module. For example, the ejector housing 122A may be depressible to unlatch the memory module and also eject the memory module (e.g., based on lever 138A), as a result of the single depressing motion.

FIG. 1B is a top view of a system 100B including an ejector 120B and memory connector 130B according to an example. The ejector housing 122B includes an ejector cutout 124B, between which the lever 138B is visible.

The ejector cutout 124B may provide guidance during insertion and ejection of the memory module, encouraging proper alignment of the memory module relative to the memory connector 130B. The ejector cutout 124B may be varied to accommodate corresponding attributes of a memory module, including modules that are wider/narrower or thicker/thinner than the dimensions of the ejector cutout 124B as shown in the example of FIG. 1B. Thus, the ejector housing 122B enables the memory module to be inserted into the memory connector 130B, where it may engage the lever 138B when properly inserted. Further, the ejector cutout 124B may hold an ejected memory module in a safe, accessible position, for easy retrieval after actuating the ejector 120B.

FIG. 1C is a bottom view of a system 100C including an ejector 120C and memory connector 130C according to an example. The ejector housing 122C may interact with the lever 138C, which is shown pivotably coupled to the memory connector 130C.

FIG. 1D is a front view of a system 100D including an ejector 120D and memory connector 130D according to an example. The lever 138D is shown pivotably coupled to the memory connector 130D. In alternate examples, the lever 138D may be coupled based on a non-pivoting arrangement, such as a natural hinge.

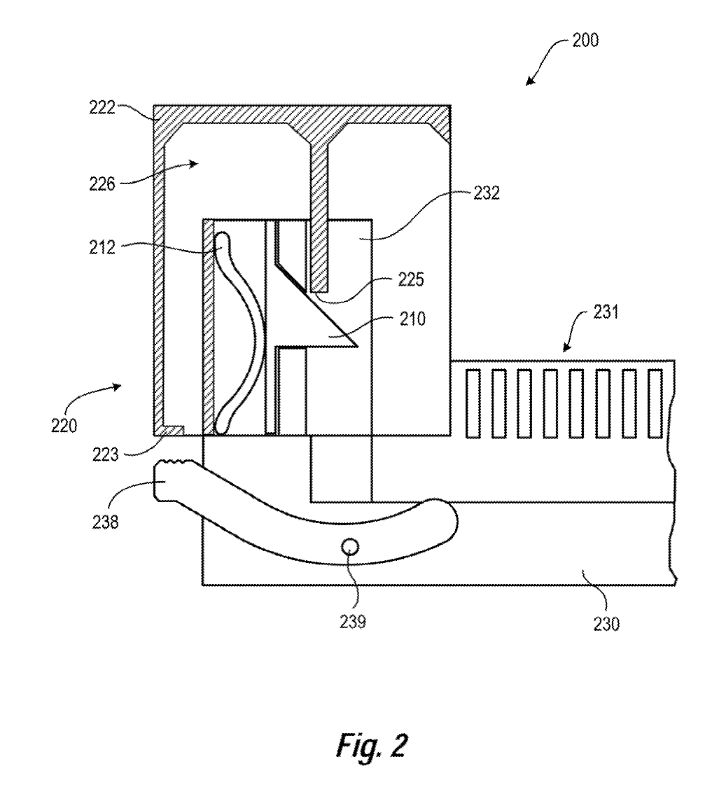

FIG. 2 is a side section view of a system 200 including an ejector 220 and memory connector 230 according to an example. The ejector 220 may include an ejector housing 222 having a first housing contact 223, a second housing contact 225, and ejector cavity 226. The ejector 220 also may include a latch 210, spring 212, and lever 238. The ejector housing 222 is shown slidably coupled to the memory connector 230, and the lever 238 is shown pivotably coupled to the memory connector 230 via the lever pivot 239. The ejector housing 222 is slidably coupled to an extension 232 of the memory connector 230. The memory connector 230 is shown having an interface 231, to electrically couple with a memory module.

The latch 210 is to interact with a memory module (not shown in FIG. 2), including receiving, retaining, and releasing the memory module. Latch 210 may have a triangular profile as shown, to enable the latch 210 to be displaced toward the spring 212 based on contact with the memory module and/or the second housing contact 225 of the ejector housing 222. In alternate examples, the latch 210 may have other profiles to latch the memory module, including shapes having rounded/curved features. In an example, the latch 210 may have a U-shape profile, corresponding to a generally U-shaped notch in a side of the memory module. The latch 210 may have a slope to enable insertion of the memory module without causing undesired levels of resistance (e.g., resistance that causes discomfort or injury when pressing on the memory module, or that prevents easy and proper insertion of the memory module). Furthermore, the latch 210 is shaped to facilitate disengagement from the memory module when desired (e.g., during ejection), to prevent a “pinching” action that might inhibit the memory module from being released. The latch 210 may be shaped and/or formed of a material to easily slide with respect to the memory module and/or other components of system 200 (e.g., housing 222 and memory connector extension 232), such as metal or plastic. The latch 210 is shown as free to slide laterally with respect to the memory connector extension 232. In alternate examples, the latch 210 may be pivotable or movable according to other arrangements to enable the latch 210 to perform the latching and releasing operations, while remaining within the footprint of the system 200. The latch 210 is biased toward the latching position based on the spring 212

The spring 212 is shown as a leaf spring. The spring 212 may be other types of springs such as coil, cantilever, torsion, etc., to bias the latch 210 toward the latched, memory retention position. In an alternate example, the latch 210 and spring 212 may be incorporated into a single piece.

The ejector housing 222 is shown in an upward position, ready to be depressed. The latch 210 may serve to bias the ejector housing 222 toward this non-depressed position. Thus, when the ejector housing 222 is depressed and released, interaction between the latch 210 and second housing contact 225 may return the ejector housing 222 to the non-depressed position. The second housing contact 225 may include a slope or rounded edge to facilitate interaction with the latch 210.

The interface 231 may serve to contribute a gripping force on an inserted memory module. In an alternate example, a gripping force of the interface 231 may be relaxed to facilitate easy memory insertion, because the latches 210 are capable of securing the inserted memory module.

The ejector housing 222 may provide a cutout to help guide memory module insertion. The memory connector extension 232 similarly may be shaped to help guide insertion of the memory module, and may be dimensioned to correspond to memory modules to be used with the system 200.

During use, a memory module may be inserted into the system 200. The latch 210 may move back based on contact with the memory module, deforming the spring 212. The system 200 can accommodate movement of the latch 210 and deformation of the spring 212 within the footprint of system 200, without a need for extra lateral space beyond the footprint to accommodate any moving parts. The latch 210 snaps into place to secure the memory module when properly inserted and in communication with the interface 231. The memory module may be ejected by depressing the ejector housing 222, which will disengage the latch 210 from the memory module based on action of the second housing contact 225 against the latch 210. The first housing contact 223 may contact the lever 238, which pivots about the lever pivot 239 and applies an upward ejecting force on the memory module.

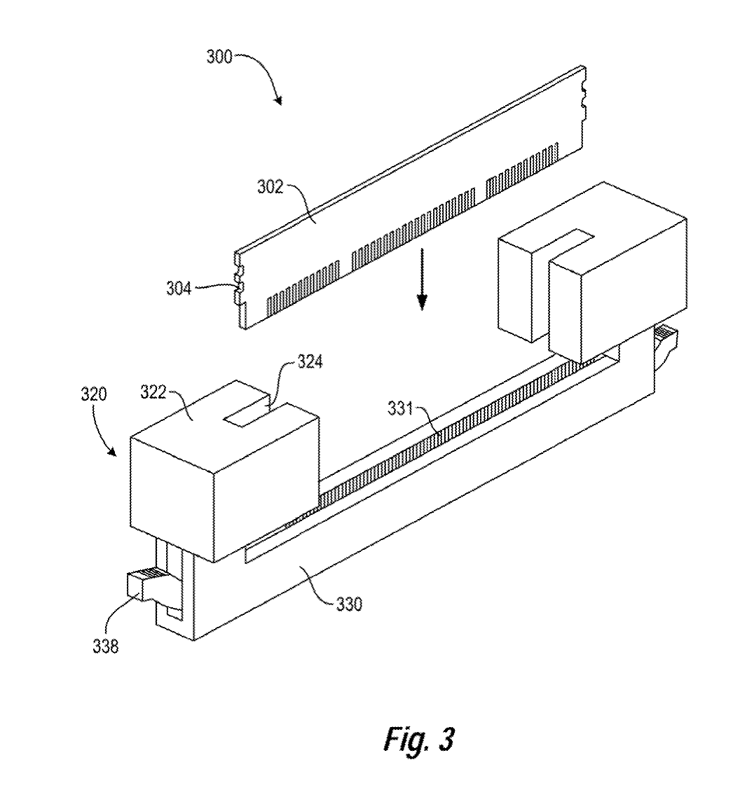

FIG. 3 is a perspective view of a system 300 including an ejector 320 and memory connector 330 according to an example. System 300 also includes ejector housing 322 and lever 338. The memory connector 330 is to receive the memory module 302 via the interface 331. The ejector housing 322 may guide insertion of the memory module 302 based on the ejector cutout 324. The ejector 320 may retain the memory module 302 based on memory notch 304.

The memory module 302 illustrates a general motion of insertion relative to the ejector 320 and memory connector 330. Thus, the insertion of the memory module 302 is along a plane generally shared with the vertical actuation motion of the ejector 320.

The memory module 302 may be inserted through the ejector cutout 324 by pushing the memory module downward as indicated by the arrow. Insertion force is reduced, because the latch within the ejector 320 is displaceable based on a spring force, and there is no need to actuate levers or other more massive structures. The system 300 may provide physical and audible feedback confirmation in response to achieving proper insertion of the memory module. For example, the ejector housing 322 may visibly jump in response to its latch snapping into the retention position against the memory module notch 304. Further, the latch may provide a snapping sound. Accordingly, a user is provided with multiple forms of confirmation of proper memory insertion, reducing the likelihood of improperly inserted memory modules 302.

The system 300 may include alternative designs to achieve the aforementioned benefits. For example, the ejector housing 322 (and/or other components such as the lever 338, memory connector 330, and so on) may be made slimmer to accommodate memory connectors 330 being placed closer together. The ejector housing 322 also may be made to have a shorter lateral dimension, e.g., resulting in a shallower ejector cutout 324. In an alternate example, the ejector cutout 324 may be omitted (e.g., based on reducing lateral dimension of the ejector housing 322 to allow passage of the memory module 302).

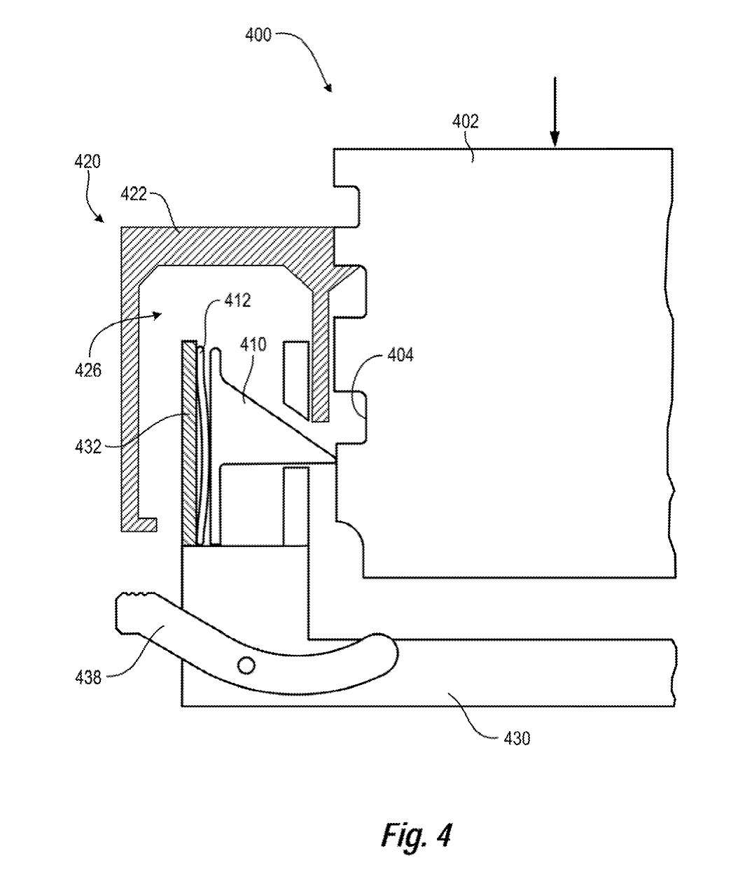

FIG. 4 is a side section view of a system 400 including an ejector 420 and memory connector 430 according to an example. The ejector 420 includes ejector housing 422, ejector cavity 426, latch 410, spring 412, and lever 438. The memory connector 430 is to receive the memory module 402, and the latch 410 is to retain the memory module 402 via notch 404. The ejector 420 may be coupled to the memory connector 430 via the extension 432 of the memory connector 430.

The memory module 402 is shown partially inserted into the memory connector 430, such that an edge of the memory module 402 has depressed the latch 410 onto the spring 412. The spring 412 has deformed, and the ejector cavity 426 can accommodate the vertical expansion of the spring 412. Although not shown in FIG. 4, the ejector housing 422 may move downward corresponding to riding the edge of the latch 410 as it retracts. The memory module 402 may be further inserted downward in the direction of the arrow shown, and seated into the memory connector 430, enabling a contacting edge of the latch 410 to pass an edge of the memory module 402 corresponding to the recessed notch 404. Upon insertion of the memory module 402 into this proper position, the spring 412 will be allowed to push the latch 410 into the retaining (latched) position. Relaxation of the spring 412, and/or motion/collision of the latch 410 with ejector housing 422 and/or the connector extension, may provide an audible ‘snap’ associated with the latch 410 assuming the latched/retention position in the notch 404 of the memory module 402. This snapping action also may cause the ejector housing 422 to visibly ‘jump’ into its original position (e.g., as shown non-depressed in FIG. 4). The memory module 402 would then be completely seated into the memory connector 430, i.e., demonstrating proper insertion of the memory module 402, ensuring good electrical contact and communication with robust physical retention. Furthermore, the latching motion is accomplished without a need for side-to-side movement, as the latch 410 is allowed to move without needing to leave the footprint of the memory connector 430.

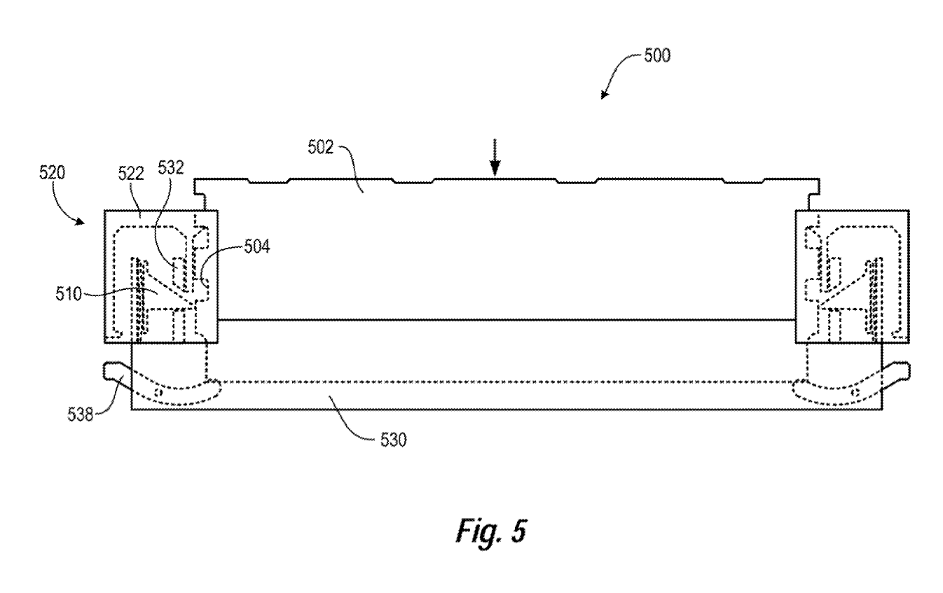

FIG. 5 is a side view of a system 500 including an ejector 520 and memory connector 530 according to an example. The memory connector 530 is to receive the memory module 502, e.g., based on latching at notch 504 of the memory module 502. The memory connector 530 includes an extension 532, to which the ejector 520 is coupled. The ejector 520 includes ejector housing 522, latch 510, and lever 538.

Thus, FIG. 5 illustrates the partial insertion of a memory module 502 into a full system 500, wherein contact with side edges of the memory module 502 are causing the latches 510 to retract, and a bottom edge of the memory module 502 is just contacting the levers 538. Accordingly, when the memory module 502 is further pushed downward and fully seated, the levers 538 will be slightly further pivoted and the latches 510 will return to the latched/retention position.

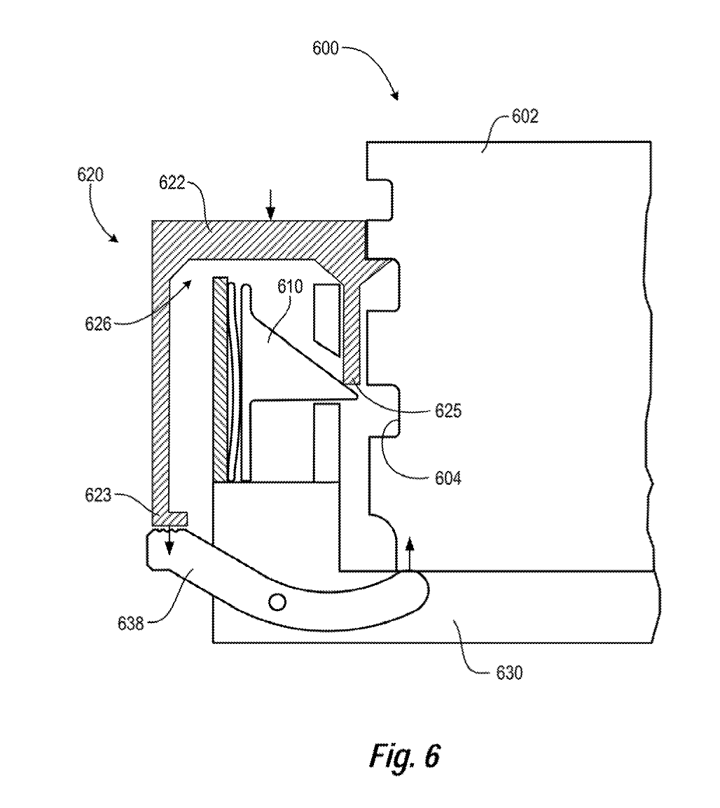

FIG. 6 is a side section view of a system 600 including an ejector 620 and memory connector 630 according to an example. The memory connector 630 is to receive the memory module 602, e.g., based on latching at notch 604 of the memory module 602. The ejector 620 is coupled to the memory connector 630, and includes ejector housing 622, ejector cavity 626, first housing contact 623, second housing contact 625, latch 610, and lever 638.

The arrows in FIG. 6 illustrate force/motion of the ejection actuation of system 600, motions which generally may be along the same vertical plane of actuation as each other and a plane of insertion/ejection of the memory module 602. For example, ejection may be accomplished based on a vertically downward force on the ejector housing 622, without a need for a user to pull upward on the memory module 602 itself to apply the unseating force.

When removing the memory module 602, the vertical press on the ejector housing 622 can accomplish both unlatching and ejecting of the memory module 602, in one swift push. Accordingly, operation of examples provided herein do not incur a need for additional overhead in terms of operational knowledge to remove the memory module 602, because all functions may be accomplished with a single, simple action of depressing the ejector housing 622. Although not specifically illustrated, a top surface of the ejector housing 622 may be contoured to include a thumb grip, and/or may include a non-slip surface, such as ridges, roughening, rubber coatings, etc.

To remove the memory module 602 from the memory connector 630, a user may press downwards (as shown by the arrow) on the ejector housing 622. The ejector housing 622 is to contact the lever 638 based on first housing contact 623, and contact the latch 610 based on second housing contact 625. Accordingly, dimensions of the ejector housing 622 may be varied to affect when such contacts occur relative to each other. Similarly, the lever 638 itself may be varied to affect timing of the contacts during downward motion of the ejector housing 622. The dimensions may be chosen appropriately to function as release timing. In an example, the second housing contact 625 may be dimensioned to make first contact, to depress the latch 610 and remove it from the recessed notch 604 of the memory module 602. Following the release of the edge of the memory module 602, the first housing contact 623 may then make contact with the lever 638. Thus, the first housing contact 623 may depress the lever 638 after the latch 610 is disengaged, resulting in an ejection force on a lower edge of the memory module as indicated by the arrow, forcing the unlatched memory module 602 upwards and out of the fully seated position in the memory connector 630. In alternate examples, the timing of the contacts may be altered, to make contact in reverse order than that described, or may make contact simultaneously. The ejected memory module 602 may be retained loosely and safely, in a disengaged state, by the system 600 (e.g., balanced by ejector cutouts and/or a memory connector extension guide), ready to be further handled/removed. In alternate examples, the system 600 may include features to prevent the memory module 602 from becoming fully separated from the system 600 in response to being ejected (e.g., going airborne), such as a slight friction between the memory module 602 and system 600.

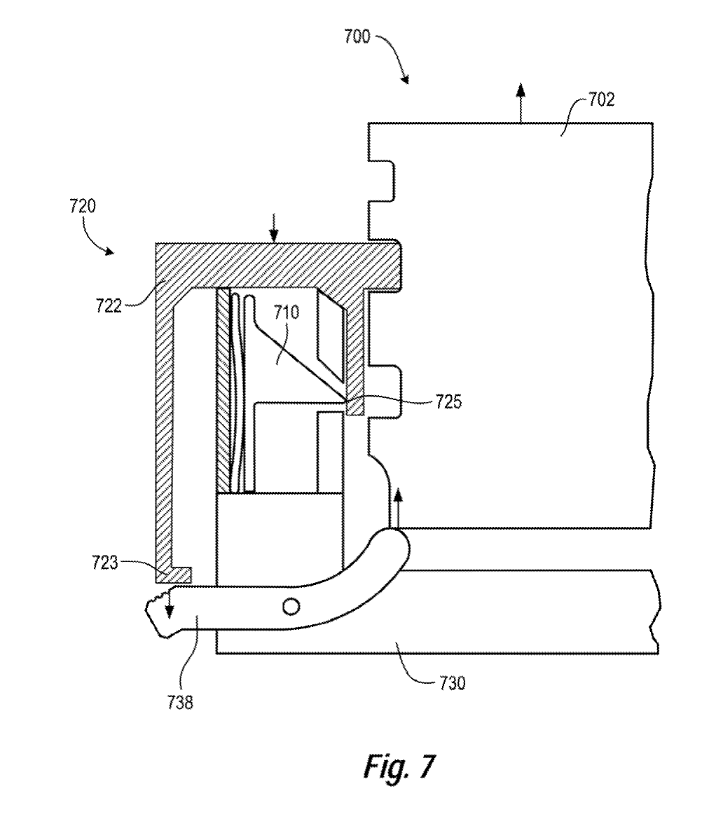

FIG. 7 is a side section view of a system 700 including an ejector 720 and memory connector 730 according to an example. The memory connector 730 is to receive the memory module 702. The ejector 720 is coupled to the memory connector 730, and includes ejector housing 722, first housing contact 723, second housing contact 725, latch 710, and lever 738.

The ejector housing 722 is shown fully depressed, wherein the lever 738 has been pivoted to disengage and eject the memory module 702 from the memory connector 730. Thus, an underside of the ejector housing 722 is in contact with an upper portion of the extension structures that extend upward from the memory connector 730.

In contrast to the example of FIG. 6 showing a flat upper surface, the upper surface of a portion of an extension structure is slanted in FIG. 7 to accommodate the corresponding slant on the underside of the ejector housing 722. Such features may be varied as desired, taking into account a thickness and/or strength of the materials and a desire to include additional reinforcement/webbing at corners, and/or making the components thin and light in view of the particular materials used.

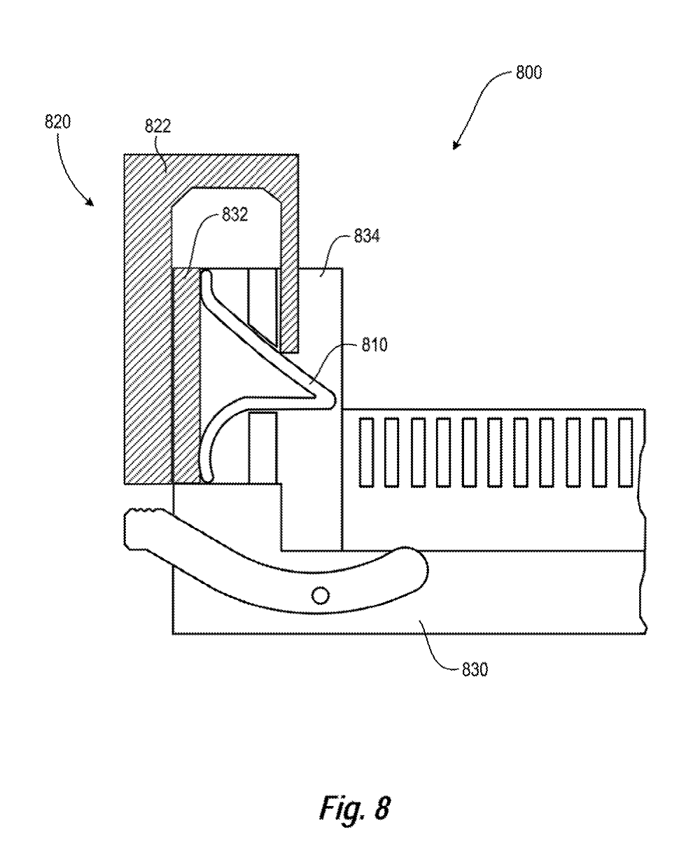

FIG. 8 is a side section view of a system 800 including an ejector 820 and latch 810 according to an example. The ejector 820 is coupled to extension 832 of the memory connector 830. The memory connector 830 includes a memory connector guide 834. The ejector 820 includes ejector housing 822 and latch 810.

In contrast to earlier examples, the example of system 800 illustrates the latch 810 being formed to include the spring as a single latch/spring piece, and formed to including rounded curves. Thus, the latch 810 may retain its shape to ensure latching operations, while deforming as desired to provide a spring force. The memory connector extension 832 and the ejector housing 822 may accommodate spring deformation/extension during operation, without a need for extending laterally beyond a footprint of the memory connector 830.

The ejector housing 822 is also shown having a thicker solid wall, to provide a first housing contact for the lever and establish lateral alignment of the ejector housing 822 relative to the memory connector extension 832. Such thickness variation is yet another example of how dimensions may be varied as desired to obtain various spacing/timing/alignment/strength etc. characteristics.

Additionally, the ejector housing 822 is shown with a reduced lateral profile, extending approximately to the second housing contact above the latch 810. Thus, the ejector housing 822 does not include lateral extensions that would form an ejector cutout to guide memory module insertion via the ejector housing 822 as described in foregoing examples. Accordingly, guidance of memory module insertion (and corresponding stabilizing of ejected memory modules) may be provided by a portion of the memory connector extension 832, e.g., by the memory connector guide 834. In alternate examples, the memory connector guide 834 may be included along with the inclusion of an ejector cutout of the ejector housing 822, or one/both may be removed.

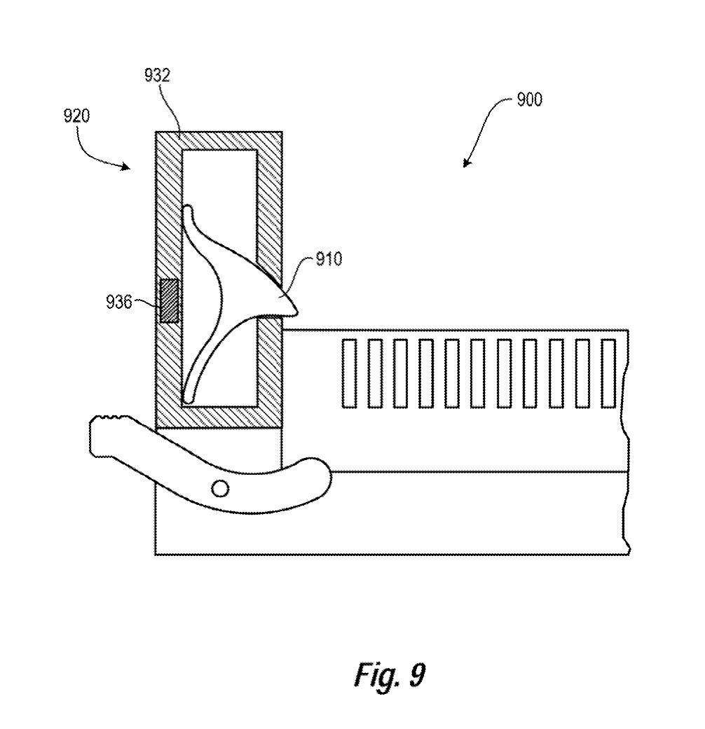

FIG. 9 is a side section view of a system 900 including an ejector 920 and latch 910 according to an example. The ejector 920 may include and/or be formed partially from memory connector extension 932. Ejector 920 includes latch 910 and memory connector bump 936. An ejector housing is not shown in FIG. 9, to reveal the memory connector bump 936.

The latch 910 is shown formed as a single piece, based on a curved triangular protrusion and leaf spring extensions. Accordingly, the latch 910 may smoothly interact with the memory module and the ejector housings, while operating efficiently within the memory connector extension 932 and avoiding binding or pinching. An ejector housing may be assembled onto the system 900, e.g., based on snap-together assembly retained by the memory connector bump 936.

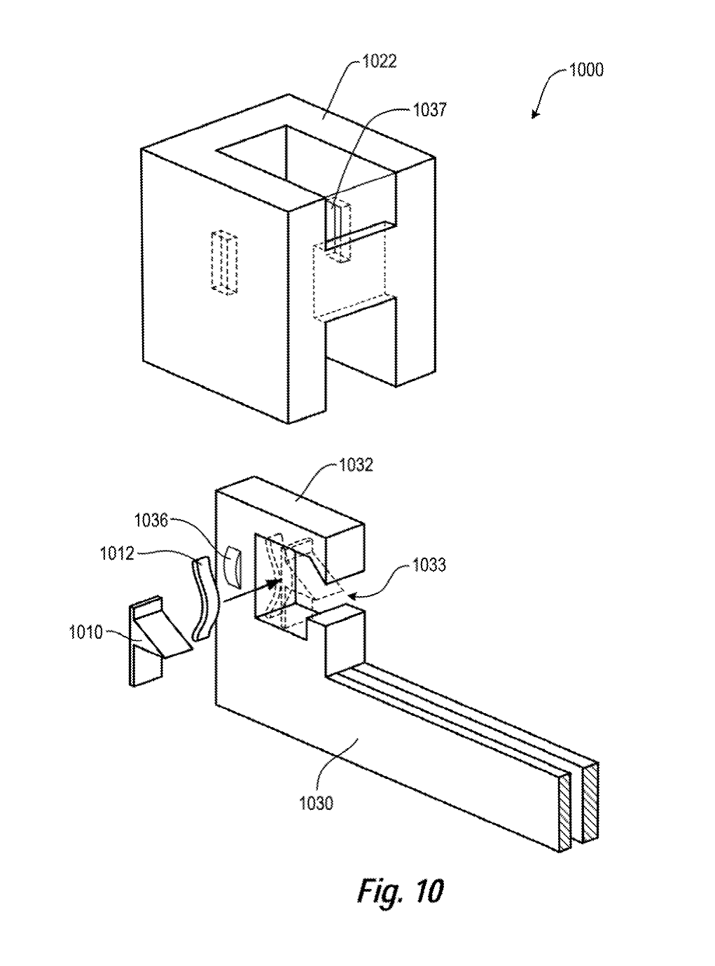

FIG. 10 is an exploded perspective view of a system 1000 including an ejector housing 1022 and memory connector 1030 according to an example. The ejector housing 1022 includes a groove 1037, which may cooperate with memory connector bump 1036 to couple the ejector housing 1022 to the memory connector 1030. The memory connector 1030 includes an extension 1032 and cavity 1033, at which the latch 1010 and spring 1012 may be received.

Positions of the bump and groove of the ejector housing 1022 and memory connector extension 1032 may be reversed, and alternate arrangements may be used to couple the ejector housing 1022 to the memory connector 1030. When assembled together, the bump and groove system may keep the ejector housing 1022 seated, in the event the system 1000 is disturbed (being turned upside-down, violent latching and unlatching events, etc.).

The ejector housing 1022 may serve to retain the assembly of various components within the connector cavity 1033. As shown, the latch 1010 and spring 1012 are approximately the same thickness as the memory connector 1030, enabling the components to smoothly slide within the connector cavity 1033 without falling out or becoming improperly oriented, ensuring correct operation of the system 1000 over many operational cycles.

The ejector housing 1022 includes a bridge across its open edge, to actuate the latch 1010. The bridge is shown as one example, and may be varied to provide the interaction with the latch 1010 during insertion/ejection operations, to provide the associated visual and/or audible feedback of proper memory module insertion/ejection as described above regarding alternate examples.

The memory connector extension 1032 is shown extending above the internal components, to create the connector cavity 1033. Thus, the connector extension 1032 may prevent the latch 1010 and spring 1012 from being forced upward, e.g., during attempted removal of the memory module, or disturbances to the system 1000.

Assembly of the components of system 1000 may be accomplished by slotting into the connector cavity 1033 the leaf spring 1012 and triangular latch 1010, e.g., from a side of the memory connector 1030. The ejector housing 1022 may be installed onto the assembly of the memory connector 1030 and associated components, snapped into place to secure them within the connector cavity 1033, while enabling the ejector housing 1022 to be slidably secured via the bump and groove arrangement.

What is claimed is:

1. A system comprising:
a memory connector to receive a memory module usable in a computing system;
a latch to retain the memory module seated in the memory connector; and
an ejector to disengage the latch into a release position, and eject the memory module, based on depressing the ejector.

2. The system of claim 1, wherein the latch is biased toward a retention position, and is displaceable to the release position based on insertion of the memory module; wherein the latch is to audibly snap into the retention position upon proper insertion of the memory module into the memory connector.

3. The system of claim 1, wherein the latch further comprises a spring to bias the latch toward the retention position.

4. The system of claim 1, wherein the latch is formed from a spring as a single piece.

5. The system of claim 1, wherein the ejector is actuatable along a plane of insertion of the memory module, to disengage the latch and depress a lever to eject the memory module.

6. The system of claim 1, wherein the ejector includes an ejector housing to retain the latch within the memory connector, and provide a depress surface to depress the ejector housing.

7. The system of claim 1, wherein the ejector housing includes an ejector cutout to guide memory insertion.

8. The system of claim 1, wherein the memory connector includes an extension to movably mount the latch and an ejector housing of the ejector.

9. The system of claim 8, wherein the ejector housing is slidably secured to the extension based on a bump and groove arrangement, to enable snap-together assembly of the ejector housing to the extension.

10. The system of claim 1, wherein the memory connector includes a cavity to house the latch.

11. The system of claim 1, wherein the memory connector includes an extension cutout to guide insertion of the memory module.

12. A computing system comprising:
a memory connector to receive a memory module;
a latch to retain the memory module seated in the memory connector, wherein the latch is retained in a cavity of the memory connector; and
an ejector slidably coupled to the memory connector to disengage the latch into a release position, and eject the memory module, based on depressing the ejector.

13. The computing system of claim 12, wherein the memory connector is to receive the memory module along a plane of insertion, and the ejector is depressible along the plane of insertion, and the latch is to bias the ejector toward a default position.

14. A method, comprising:
receiving, at a memory connector, a memory module usable in a computing system;
retaining, by a latch, the memory module seated in the memory connector;
disengaging, by an ejector, the latch into a release position based on depressing the ejector; and
ejecting the memory module, based on depressing the ejector.

15. The method of claim 14, further comprising:
displacing the latch to a release position based on insertion of the memory module; and
audibly snapping the latch into a retention position upon proper insertion of the memory module into the memory connector.
